(19) United States
(12) Patent Application Publication
(10) Pub. No.: US 2025/0180979 A1
(43) Pub. Date: Jun. 5, 2025

(54) MASK REPAIR APPARATUS AND METHODS

(71) Applicant: Taiwan Semiconductor Manufacturing Co., Ltd., Hsinchu (TW)

(72) Inventors: Meng-Han HUNG, Hsinchu (TW); Chih-Wei WEN, Hsinchu (TW); Chung-Hung LIN, Hsinchu (TW); Kuan-Shien LEE, Hsinchu (TW)

(21) Appl. No.: 18/527,587

(22) Filed: Dec. 4, 2023

(51) Int. Cl. G03F 1/22; G03F 7/00; H01L 21/027

(52) U.S. Cl. CPC G03F 1/22; G03F 7/70733; H01L 21/027

(57) ABSTRACT

A method includes: positioning a mask in a processing chamber of a mask repair apparatus; determining whether a first abnormality is present by a first gas analysis device during forming a first vacuum in a column over the processing chamber; determining whether a second abnormality is present by a second gas analysis device during forming a second vacuum in the processing chamber; determining whether a third abnormality is present by a third gas analysis device during flowing a process gas into the processing chamber; determining whether a fourth abnormality is present by a fourth gas analysis device during directing an electron beam or ion beam at the mask with the process gas in the processing chamber; and in response to determining that one of the first, second, third or fourth abnormalities is present: halting the directing an electron beam or ion beam at the mask; and performing a repair associated with the first, second, third or fourth abnormality that is present.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a diagrammatic schematic view of an apparatus for photolithography in accordance with various embodiments.

FIG. 1B is a diagrammatic schematic view of an apparatus for electron beam manufacturing according to embodiments of the present disclosure.

FIGS. 2-4 are views of an electron beam apparatus having out gas detection according to various aspects of the present disclosure.

FIGS. 5 and 6 are flowcharts of methods according to various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Terms such as “about,” “roughly,” “substantially,” and the like may be used herein for ease of description. A person having ordinary skill in the art will be able to understand and derive meanings for such terms.

The present disclosure is generally related to charged particle lithography systems and methods, e.g., electron beam and ion beam lithography systems and methods. More particularly, the present disclosure is related to apparatuses and methods for repairing a mask or reticle used in a photolithography apparatus, such as an extreme ultraviolet (EUV) lithography apparatus.

In an EUV lithography apparatus, a reflective mask or reticle may be positioned in a chamber to reflect light based on a pattern that is present on the mask. The pattern may include first regions that are highly reflective and second regions that are less reflective or not reflective. In some cases, the mask may include one or more defects that will render errors in the reflection of light, and generate defects on a material layer that is patterned based on the reflected light. Examples of defects that may be present on or in an EUV mask include blank defects, phase defects, absorber defects, particle contamination, pellicle defects and printed defects. Blank defects may be inherent in a multi-layer mirror substrate of the mask and can include bumps, pits, or inclusions. Phase defects may be caused by imperfections in the reflective multi-layer structure and can alter the phase of the reflected EUV light. Absorber defects are defects in the absorber layer, such as over-etching or under-etching, leading to incorrect feature sizes or shapes. Particle contamination occurs when particles settle on the reticle during manufacturing, handling, or even during the lithography process. Pellicle defects may occur when a pellicle is used to protect the reticle and can include defects in the pellicle itself or between the pellicle and the reticle can occur. Printed defects are defects that occur during the lithography process but manifest on the reticle, such as double exposure or alignment errors. Some defects, such as absorber defects, that occur due to over-etching or under-etching, can be repaired by an electron-beam-induced deposition or “EBID” or by an electron-beam-induced etch or “EBIE.”

The EBID or EBIE process may be performed by directing an electron beam or “e-beam” or an ion beam into a chamber in which the mask to be repaired in positioned. The chamber is generally held under vacuum to avoid deflection or scattering of the e-beam or ion beam prior to reaching the mask. The level of vacuum in the chamber is monitored to avoid poor yield in the repair process. The chamber is also cleaned periodically to avoid outgassing by contaminants that may be present in the chamber. One method for monitoring the vacuum and potential outgassing is performing a “fake” or dry-run deposition or etch. The fake deposition or etch includes performing e-beam treatment on the reticle in the absence of any gas precursor. During the fake deposition, chamber cleanliness may be monitored, but identity of any contaminant may be unknown.

In embodiments of the disclosure, chamber contaminant outgassing and vacuum level are monitored to prevent instability of the EBID and/or EBIE process, including monitoring for leakages and/or process gas impurities. The monitoring is beneficial to reduce mask contamination and scrap and/or damage to components of the apparatus. A gas analysis device may detect content of exhausted gas in a mask repair apparatus. The gas analysis device may monitor chamber vacuum status and analyze contents of contamination gas(es) (e.g., outgassing or process gas impurities) in the mask repair apparatus. The gas analysis device may be connected to a pumping line to monitor leakage and contaminant status of the mask repair apparatus.

Inclusion of the gas analysis device may accord various benefits. The gas analysis device may detect contents of process gas(es) and/or process byproducts in the mask repair apparatus in real-time to improve repair process stability. The gas analysis device may monitor contamination gas in the vacuum chamber and analyze out gas source to improve periodic maintenance scheduling, which may prevent mask damage. The gas analysis process may aid in confirming a contamination gas source and preventing mask scrap due to contamination. The gas analysis process may monitor leakage status of the mask repair apparatus in tandem with or as a replacement to monitoring vacuum pressure.

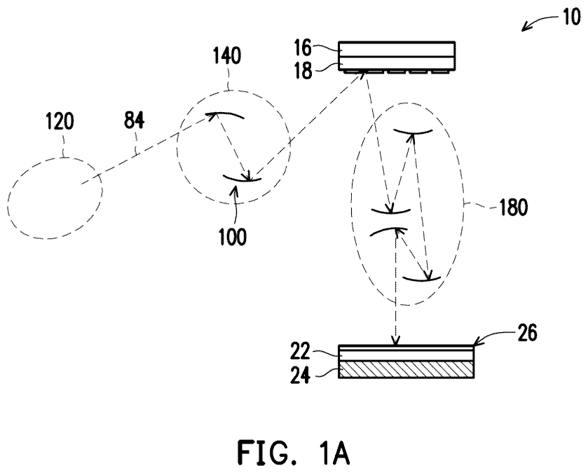

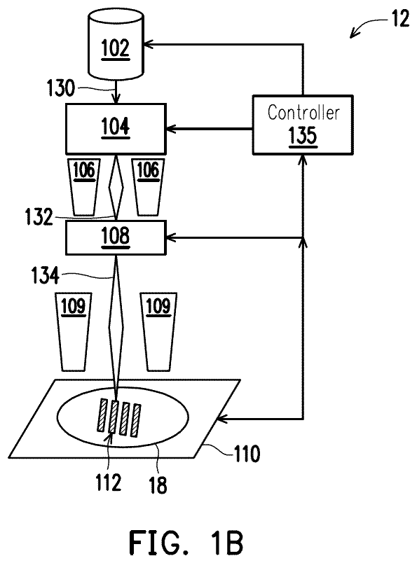

FIG. 1A is a schematic and diagrammatic view of a lithography exposure system or apparatus 10, in accordance with some embodiments. The lithography exposure system 10 is described in detail to provide context for understanding a mask repair apparatus that includes gas detector(s) beneficial for detecting contaminants, process gas impurities, leakage and the like.

In some embodiments, the lithography exposure system 10 is an extreme ultraviolet (EUV) lithography system designed to expose a resist layer by EUV radiation, and may also be referred to as the EUV system 10. The EUV system 10 may also be referred to as an EUV scanner or lithography scanner. The lithography exposure system 10 includes a light source 120, an illuminator 140, a mask stage 16, a projection optics module (or projection optics box (POB)) 180 and a substrate stage 24, in accordance with some embodiments. The elements of the lithography exposure system 10 can be added to or omitted, and the disclosure should not be limited by the embodiment.

The light source 120 is configured to generate light radiation 84 having a wavelength ranging between about 1 nm and about 300 nm in certain embodiments. In one particular example, the light source 120 generates an EUV radiation with a wavelength centered at about or substantially 13.5 nm. Accordingly, the light source 120 is also referred to as an EUV radiation source. However, it should be appreciated that the light source 120 should not be limited to emitting EUV radiation. The light source 120 can be utilized to perform any high-intensity photon emission from excited target fuel.

In various embodiments, the illuminator 140 includes various refractive optic components, such as a single lens or a lens system having multiple reflectors 100, for example lenses (zone plates) or alternatively reflective optics (for EUV lithography exposure system), such as a single mirror or a mirror system having multiple mirrors in order to direct light from the light source 120 onto the mask stage 16, particularly to a mask 18 secured on the mask stage 16. In embodiments in which the light source 120 generates light in the EUV wavelength range, reflective optics are employed. In some embodiments, the illuminator 140 includes at least two reflectors, at least three reflectors, or more.

The mask stage 16 is configured to secure the mask 18. In some embodiments, the mask stage 16 includes an electrostatic chuck (e-chuck) to secure the mask 18. One reason an e-chuck is beneficial is that gas molecules absorb EUV radiation and the e-chuck is operable in the lithography exposure system for the EUV lithography patterning that is maintained in a vacuum environment to avoid EUV intensity loss. In the present disclosure, the terms mask, photomask, and reticle are used interchangeably. In the present embodiment, the mask 18 is a reflective mask. One example structure of the mask 18 includes a substrate with a suitable material, such as a low thermal expansion material (LTEM) or fused quartz. In various examples, the LTEM includes TiO2 doped SiO2, or other suitable materials with low thermal expansion. The mask 18 includes a reflective multilayer deposited on the substrate. The mask stage 16 is operable to translate in two horizontal directions, such as an X-axis direction and a Y-axis direction, so as to expose multiple different regions of the semiconductor wafer 22 to light having a pattern generated by the mask 18. The semiconductor wafer 22 may have a mask layer 26 thereon, which may be a photoresist layer that is sensitive to the light carrying the pattern of the mask 18.

The projection optics module (or projection optics box (POB)) 180 is configured for imaging the pattern of the mask 18 on to a semiconductor wafer 22 secured on the substrate stage 24 of the lithography exposure system 10. In some embodiments, the POB 180 has refractive optics (such as for a UV lithography exposure system) or alternatively reflective optics (such as for an EUV lithography exposure system) in various embodiments. The light directed from the mask 18, carrying the image of the pattern on the mask, is collected by the POB 180. The illuminator 140 and the POB 180 may be referred to collectively as an optical module of the lithography exposure system 10. In some embodiments, the POB 180 includes at least six reflective optics.

In some embodiments, the semiconductor wafer 22 may be made of silicon or other semiconductor materials. Alternatively or additionally, the semiconductor wafer 22 may include other elementary semiconductor materials such as germanium (Ge). In some embodiments, the semiconductor wafer 22 is made of a compound semiconductor such as silicon carbide (SiC), gallium arsenic (GaAs), indium arsenide (InAs), or indium phosphide (InP). In some embodiments, the semiconductor wafer 22 is made of an alloy semiconductor such as silicon germanium (SiGe), silicon germanium carbide (SiGeC), gallium arsenic phosphide (GaAsP), or gallium indium phosphide (GaInP). In some other embodiments, the semiconductor wafer 22 may be a silicon-on-insulator (SOI) or a germanium-on-insulator (GOI) substrate.

In addition, the semiconductor wafer 22 may have various device elements. Examples of device elements that are formed in the semiconductor wafer 22 include transistors (e.g., metal oxide semiconductor field effect transistors (MOSFET), complementary metal oxide semiconductor (CMOS) transistors, bipolar junction transistors (BJT), high voltage transistors, high-frequency transistors, p-channel and/or n-channel field-effect transistors (PFETs/NFETs), etc.), capacitors, inductors, diodes, and/or other applicable elements. Various processes are performed to form the device elements, such as deposition, etching, implantation, photolithography, annealing, and/or other suitable processes. In some embodiments, the semiconductor wafer 22 is coated with a resist layer (e.g., mask layer 26) sensitive to the EUV radiation. Various components including those described above are integrated together and are operable to perform lithography processes.

The lithography exposure system 10 may include other modules or be integrated with (or be coupled with) other modules, such as a cleaning module or apparatus or system designed to provide hydrogen gas to the light source 120 and a tin supply system designed to provide liquid tin to the light source 120. The hydrogen gas helps reduce contamination in the light source 120. The cleaning system may clean a collector of the light source 120, but is not limited thereto. For example, tin debris may settle on a variety of components of the lithography exposure system 10, and the cleaning system may expel the hydrogen gas toward the various components to remove the tin debris.

Prior to positioning the mask 18 in the system 10, the mask 18 may be inspected to determine whether defects are present in the mask 18. In response to defects being present, the mask 18 may be sent for repair or rework prior to being used in the system 10. The repair or rework process may be conducted via a mask repair apparatus, which may include a beam source, such as an ion beam source or e-beam source. A mask repair apparatus 12 in accordance with various embodiments is described with reference to FIGS. 1B and 2-4.

FIG. 1B shows a diagram of an electron beam or ion beam system 12 that includes a controller 135, a charge particle source, e.g., an electron source 102, one or more focusing lenses 106 and 109, a beam forming unit 104, and a shutter-deflector unit 108. The system 12 is one example of an ion or electron beam system, and some components may be omitted from view for simplicity of illustration. The electron-beam system 12 uses electron-based imaging for mask repair. In some embodiments, the focusing lenses 106 and 109 of FIG. 1B are cross-sections of a magnetic cylinder, e.g., a magnetic disc, surrounding the electron beam and having a central opening for the electron beam to pass through. In some embodiments, the magnetic field of the magnetic cylinder is used to focus the electron beam.

In the electron beam system 12, the electron or ion source 102 provides an electron or ion emission 130. The electron emission 130 from the electron source 102 is received by the beam forming unit 104. The beam forming unit 104 generates an electron beam 132. The electron beam 132 is focused by one or more focusing lenses 106. The electron beam 132 is received by a shutter-deflector unit 108. The shutter-deflector unit 108 may turn the electron beam on and off. When the shutter-deflector unit 108 is open and the electron beam is turned on, an electron beam 134 exits the shutter-deflector unit 108, passes through focusing lenses 109, and focuses on the mask 18 to produce the repair pattern 112 in the mask 18.

In some embodiments, the mask 18 is on a stage 110 and the controller 135 moves the stage 110 to generate the repair pattern 112 by movement of the stage 110. In some embodiments, the shutter-deflector unit 108 of the system 12 deflects the electron beam 134, based on the repair pattern, to generate the repair pattern 112 on the mask 18. In some embodiments, in addition to the movement of the stage 110, the shutter-deflector unit 108 deflects the electron beam 134 to generate the repair pattern 112 in the mask 18. In some embodiments, the controller 135 is coupled to the electron source 102, the beam forming unit 104, the shutter-deflector unit 108, and the stage 110. The controller 135 may control the electron source 102 to adjust the intensity of electron beam 134. In some embodiments, the controller 135 receives the repair pattern and by controlling the beam forming unit 104, the shutter-deflector unit 108, and the stage 110 generates the repair pattern 112 in the mask 18. Thus, by controlling the intensity of the electron beams 132 and 134, the deflection of the electron beam 134 and/or the movement of the stage 110, the controller 135 of the electron beam lithography systems 100 may generate the repair pattern 112 in the mask 18.

In some embodiments, the charged particle source of FIG. 1B is an ion beam source. The beam forming unit 104, focusing lenses 106 and 109, and the shutter-deflector unit 108 focus an ion beam on the mask 18 to generate the repair pattern 112 on the mask 18. In some embodiments, the ion beam includes hydrogen ions, which are several hundred times heavier than electrons. Thus, in some embodiments, the energy of the ion beam, compared to the electron beam, becomes less scattered and creates more local impact inside the mask material. In some embodiments, gallium ions or helium ions are used for ion beam lithography.

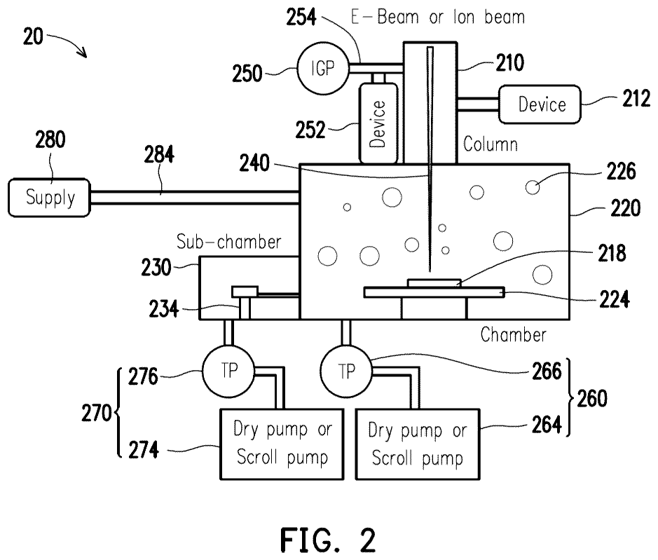

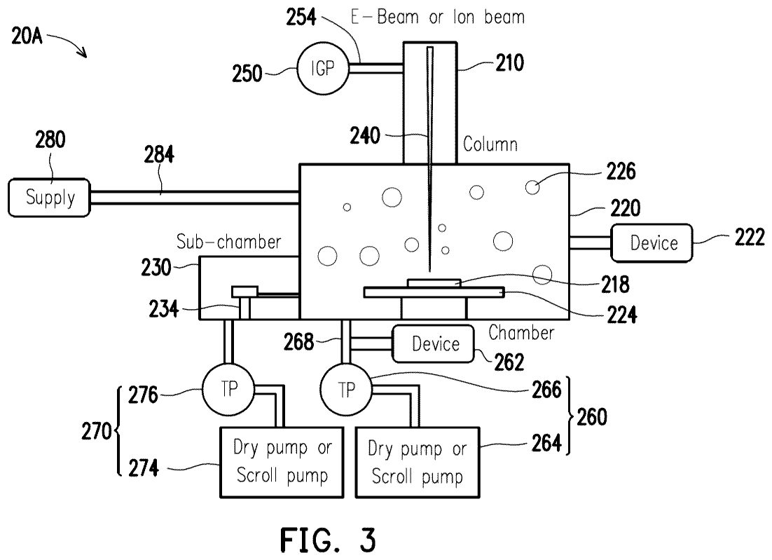

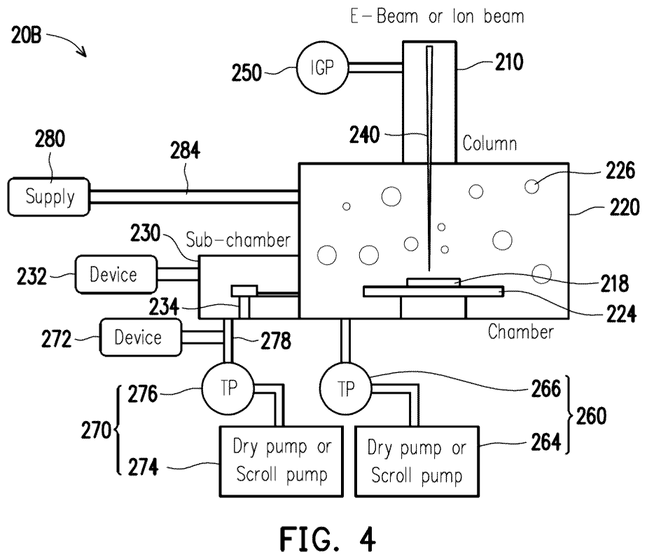

FIGS. 2-4 are diagrammatic schematic views of mask repair apparatuses or “systems” 20, 20A, 20B in accordance with various embodiments. FIG. 2 illustrates an embodiment in which one or more gas analysis devices are positioned on an electron beam column or ion beam column of the mask repair apparatus 20. FIG. 3 illustrates an embodiment in which one or more gas analysis devices are positioned at a chamber of the mask repair apparatus 20A. FIG. 4 illustrates an embodiment in which one or more gas analysis devices are positioned at a sub-chamber of the mask repair apparatus 20B. In some embodiments, gas analysis devices are positioned at the column, the chamber, the sub-chamber, or a combination thereof. Namely, two or all of the embodiments of FIGS. 2-4 may be combined in some embodiments.

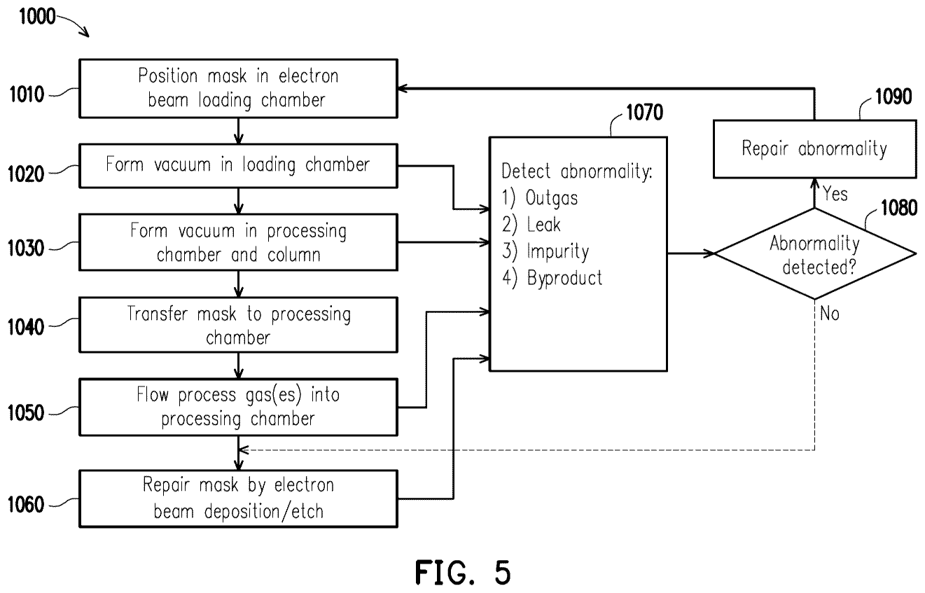

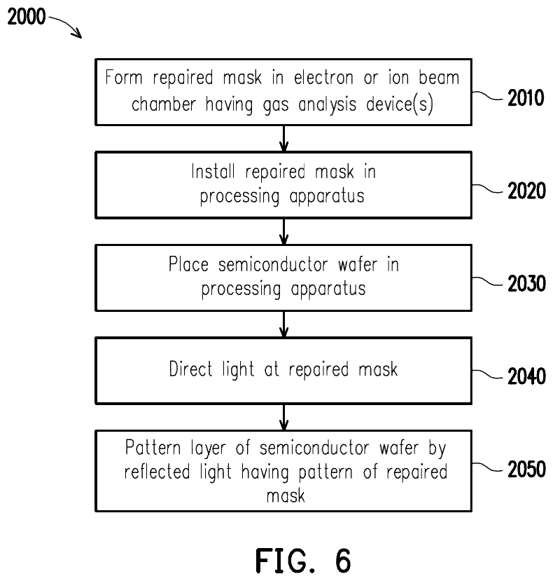

FIGS. 5 and 6 are flowcharts illustrating methods 1000, 2000 of processing a semiconductor device according to various aspects of the present disclosure. The acts illustrated in FIGS. 5 and 6 may be performed in accordance with the systems 10, 12 described with reference to FIGS. 1A and 1B and/or the systems 20, 20A, 20B described with reference to FIGS. 2-4. FIGS. 5 and 6 illustrate flowcharts of methods 1000, 2000 for repairing a mask and processing a semiconductor device, according to one or more aspects of the present disclosure. Methods 1000, 2000 are examples and are not intended to limit the present disclosure to what is explicitly illustrated in methods 1000, 2000. Additional acts can be provided before, during and after the methods 1000, 2000 and some acts described can be replaced, eliminated, or moved around for additional embodiments of the methods. Not all acts are described herein in detail for reasons of simplicity. For example, acts related to identifying defects in masks or reticles prior to acts 1010 and 2010 the methods 1000, 2000 are omitted. Similarly, acts that follow the acts of methods 1000, 2000, for example, that are related to singulation and packaging of IC dies are also omitted from view and not described in detail herein. Acts of methods 1000, 2000 are described below with reference to elements of the systems 10, 12, 20, 20A, 20B of FIGS. 1A-4. It should be understood that the methods 1000, 2000 are not limited to being performed by the systems 10, 12, 20, 20A, 20B, and may be performed by systems that differ in one or more respects from the systems 10, 12, 20, 20A, 20B in other embodiments.

FIG. 2 is a diagrammatic schematic view of a system 20 in accordance with various embodiments. The system 20 may be an embodiment of the system 12 of FIG. 1B. Some components are omitted from view in FIG. 2 for simplicity of illustration.

The system 20 may include a column 210, a chamber or processing chamber 220, a sub-chamber or loading chamber 230, pumps or pump systems 250, 260, 270 and first and second gas analysis devices 252, 212.

The column 210 may generate an e-beam or ion beam 240 that is incident on a mask 218 in the chamber 220. The column 210 may include one or more components similar in most respects to the electron source 102, the focusing lenses 106 and 109, the beam forming unit 104, and the shutter-deflector unit 108 of FIG. 1B. The column 210 is positioned over the chamber 220 such that the e-beam 240 may be directed downward into the chamber 210. One or more valves may be present in the column 210 and/or the chamber 220 that open or close communication between the column 210 and the chamber 220. For example, a valve may be closed while pressure in the column 210 is drawn down to a vacuum level so as to prevent pressure in the chamber 220 from affecting pressure in the column 210. The valve may be opened to allow passage of the e-beam 240 into the chamber 220 for processing, such as repair of a mask 218.

A first pump or pump system 250 may be in fluid communication with the column 210 via a first transport line 254. In some embodiments, the first pump 250 is or includes an ion getter or “ion getter pump” (IGP) and may be referred to as the IGP 250. The IGP 250 may be a vacuum pump that operates without moving parts and is beneficial for forming ultra-high vacuum environments. The first pump 250 may work by ionizing residual gases and trapping the resulting ions on a getter material, effectively removing the ions from the vacuum chamber, e.g., the column 210. Given the sensitivity and high-precision process used for e-beam generation, the ion getter pump may be beneficial as it can maintain an extremely low-pressure environment. This is beneficial for minimizing electron scattering and thereby improving high-resolution imaging, fabrication and/or repair. In one example, operation of the first pump 250 may include sputtering, in which a high-voltage electric field is applied between a cathode and anode inside a pump chamber. This ionizes residual gas molecules. The ions are then accelerated towards the cathode due to the electric field. When the ions strike the cathode, made for example of materials like titanium, the ions cause sputtering of the cathode material. This sputtered material then chemically reacts with the ionized gas to form a stable compound that adheres to the cathode surface, effectively removing the gas molecules from the chamber.

A first gas analysis device 252 may be mounted to or included in the first transport line 254. The first gas analysis device 252 installed in the first transport line 254 of the IGP 250 may monitor out gas and/or leakage during processing. In some embodiments, the first gas analysis device 252 may monitor and/or detect one or more of H2O, CO, CO2, H2, N2, O2, CxHyOz and the like. The first gas analysis device 252 may perform one or more of mass spectrometry, Fourier transform infrared spectroscopy (FTIR), electrochemical sensing, photoionization detection, residual gas analysis, ion mobility spectrometry (IMS), or the like. The first gas analysis device 252 may include a miniaturized mass spectrometer that may be directly integrated into the first transport line 254 for performed mass spectrometry by real-time analysis. FTIR may be performed using fiber optic probes or in-line cells of the first gas analysis device 252 that can perform in-situ FTIR analysis. Electrochemical sensors may be included in the first gas analysis device 252 and used for in-situ detection of selected gases and can be installed directly in the first transport line 254. Photoionization detectors (PIDs) may be included in the first gas analysis device 252 and may be beneficial for in-situ monitoring of volatile organic compounds (VOCs). In some embodiments, the gas analysis device includes one or more residual gas analyzers (RGAs) that can be directly connected to the first transport line 254 for in-situ analysis of residual gases. Ion mobility spectrometry (IMS) may be used for inline monitoring and may be beneficial for detecting trace contaminants. Inclusion of the first gas analysis device 252 that detects out gas contaminant data is beneficial to prevent contamination of an aperture or lens of the column 210. Namely, the first gas analysis device 252 may aid in early detection of contaminants on the aperture or lens of the column 210 that are sources of detectable outgassing in the vacuum environment of the column 210. In some embodiments, the first gas analysis device 252 may detect leakage in the column 210.

A second gas analysis device 212 may be mounted to a wall (e.g., a top cover, sidewall, bottom wall, or the like) of the column 210 and may be in fluid communication with an interior of the column 210 for detecting leakage, outgassing or the like. The second gas analysis device 212 may be the same as or similar in most respects to the first gas analysis device 252 just described. The second gas analysis device 212 may perform one or more of mass spectrometry, Fourier transform infrared spectroscopy (FTIR), electrochemical sensing, photoionization detection, residual gas analysis, ion mobility spectrometry (IMS), or the like. In some embodiments, the second gas analysis device 212 is a different type of gas analysis device than the first gas analysis device 252 or is a same type of gas analysis device that has different configuration than the first gas analysis device 252. For example, the first gas analysis device 252 may be or include an RGA that is suitable for detecting a first set of gases while the first gas analysis device 252 is or includes a mass spectrometer that is suitable for detecting a second different set of gases.

In some embodiments, two or more first gas analysis devices 252 are coupled to the first transport line 254 and/or two or more second gas analysis devices 212 are coupled to the sidewall of the column 210. This may be beneficial when different types of gases and/or contaminants are being detected. For example, outgassing from contaminants on the aperture or lens may have a first chemical constituency (e.g., hydrocarbons, metal-organic compounds, metal oxides, halogen compounds, etc.) whereas leakage gases from an external environment that enter the column 210 due to the vacuum pressure may have a second, different chemical constituency (e.g., H20, N2, O2, etc.).

By detecting various contaminants, outgassing gases and impurities, the first and second gas analysis devices 252, 212 may identify or aid in identifying out gas sources, column leakage and/or source gas impurities based on a detection result. In addition to contaminants introduced during processing or as a byproduct of processing, some contaminants may be introduced via preventative maintenance or “PM.” In another example, the PM process may not be entirely sufficient to remove all contaminants from the column 210. The first and second gas analysis devices 252, 212 may provide an additional verification whether the PM process removed all or most contaminants or whether a level of contaminants in the column 210 following the PM process is above a selected threshold value (e.g., a few or fewer than one part-per-trillion or “PPT” to 1 part-per-million or “PPM,” or another suitable range). Levels may vary depending on the type of contaminant. For example, metallic component contaminants may have a threshold value of 1-5 PPT or lower, whereas water vapor, hydrocarbons and inert gases may have a threshold value of about 5-10 PPB or less to about 1 PPM or less.

The chamber 220 may be a main chamber of the apparatus 20 and may serve as a primary environment where deposition and/or etching takes place. The chamber 220 may be configured to operate under ultra-high vacuum (UHV) conditions that are beneficial to reduce contamination and improve deposition and/or etching quality. The chamber may include a mask stage 224 that is operable to hold the mask 218 and to be manipulated in multiple axes for precise alignment under the electron beam 240. The mask 218 may be an embodiment of the mask 18 described with reference to FIGS. 1A and 1B.

The chamber 220 may include a gas injection system that introduces (e.g., flows) gaseous and/or vaporized precursors 226 that interact with the electron beam 240 for deposition and/or etching. The gas injection system may include a gas supply 280 that is in fluid communication with the chamber 220 via one or more transport lines 284.

The chamber 220 may include one or more pumping systems 260 that may each include one or more different vacuum pumps 264, 266, such as turbo pumps 266 and/or dry or scroll pumps 264 beneficial for establishing and maintaining UHV conditions. In some embodiments, the turbo pump 266 is positioned between the dry or scroll pump 264 and the chamber 220. In some embodiments, the dry pump 264 is operable to draw down to a first vacuum level, then the turbo pump 266 is operable to drawn down to a second vacuum level (e.g., UHV) that is higher than the first vacuum level. It should be understood that, a higher vacuum level may be associated with a lower pressure level.

The chamber 220 may include one or more ports for detectors and/or sensors, which may include devices for real-time monitoring of deposition rate, chamber pressure, in-situ characterization of the deposited material, and the like.

The components of the chamber 220 just described may be operable individually or in combination to provide a high vacuum (e.g., 1×10⁻⁹ to 1×10⁻¹² Torr) to reduce contaminants. The components may be or include materials that resist outgassing and chemical interaction with the precursors. One or more of the components, such as the mask stage 224, may include temperature control for the mask 218, which may benefit deposition and/or etching characteristics.

The sub-chamber 230 is attached to the chamber 220 and may be operable to intake the mask 218 from the external environment (e.g., a cleanroom of a semiconductor fab) and place the mask 218 in the chamber 220. The sub-chamber 230 may be operable to remove the mask 218 from the chamber 220 and transfer the mask 218 to the external environment (e.g., to a carrier for transport to a lithography system). For example, the sub-chamber 230 may have a transfer device 234, such as a robot arm 234, positioned therein that is operable to transfer the mask 218 in to and out from the chamber 220. The robot arm 234 may be a component beneficial for automating the transfer of masks 218 between the sub-chamber 230, which may be used for pre-treatment or post-treatment processes, and the chamber 220 where the repair work is conducted. The robot arm 234 may include a gripper or end-effector operable to hold and transport masks safely without causing scratches, damage or contamination. The robot arm 234 may include one or more articulated joints, which may include 4-6 degrees of freedom, which allow for precise positioning and orientation of the mask 218. The robot arm 234 may include one or more drive mechanisms, such as stepper motors or servo motors that are beneficial for high-precision movement. The robot arm 234 may include one or more sensors, such as optical or proximity sensors that are beneficial to confirm the position of the mask 218 and provide secure transport of the mask 218 between the chambers 220, 230.

The sub-chamber 230 may be in frequent contact with the external environment. As such, the sub-chamber 230 is a likely source of contaminants into the chamber 220 and the column 210. The sub-chamber 230 may be attached to or include a pumping system 270 that is operable to draw down pressure in the sub-chamber 230. By drawing down the pressure in the sub-chamber 230, pressure in the sub-chamber 230 and the chamber 220 may be substantially equalized. The pumping system 270 may also remove contaminants from the sub-chamber 230 prior to transferring the mask 218 to and/or from the chamber 220. The pumping system 270 may include one or more of a turbo pump 276, a dry or scroll pump 274 and the like. In some embodiments, the turbo pump 276 is positioned between the dry or scroll pump 274 and the sub-chamber 230. In some embodiments, the dry pump 274 is operable to draw down to a first vacuum level, then the turbo pump 276 is operable to drawn down to a second vacuum level (e.g., UHV) that is higher than the first vacuum level.

FIG. 3 is a diagrammatic schematic view of a system 20A in accordance with various embodiments. The system 20A may be an embodiment of the system 12 of FIG. 1B and may be similar in most respects to the system 20 of FIG. 2. Some components are omitted from view in FIG. 3 for simplicity of illustration.

The system 20A may include a third gas analysis device 222 and a fourth gas analysis device 262. The third gas analysis device 222 and the fourth gas analysis device 262 may be any of the gas analysis devices described with reference to FIG. 2. Namely, the third and fourth gas analysis devices 222, 262 may each perform one or more of mass spectrometry, Fourier transform infrared spectroscopy (FTIR), electrochemical sensing, photoionization detection, residual gas analysis, ion mobility spectrometry (IMS), or the like.

The third gas analysis device 222 may be connected to the chamber 220. For example, the third gas analysis device 222 may be mounted to a sidewall of the chamber 220 and may be in fluid communication with the chamber 220, such that a gas medium inside the chamber 220 may flow into the third gas analysis device 222 from the chamber 220. The third gas analysis device 222 may be operable to detect process gas(es) (e.g., F2, Cl2, I2, NO2, Cr, TEOS, H2O, NH3, H2, CxHyOz), outgassing of contaminants, leakage gases and/or process byproducts. For example, the third gas analysis device 222 may be operable to detect impurities in process gas(es). The impurities may be introduced at the gas supply 280, in the transport line 284, or both. The third gas analysis device 222 may be operable to detect outgassing of contaminants. For example, the contaminants may be present on inner walls of the chamber 220, surfaces of the mask stage 224, the mask 218 itself, or combinations thereof. The third gas analysis device 222 may be operable to detect leakage of external environmental air into the chamber 220. The third gas analysis device 222 may be operable to detect byproducts of the EBID or EBIE process. For example, some material particles formed by the reacted gas(es) may not deposit or attach on the surface of the mask 218, but instead may float in the chamber 220. The third gas analysis device 222 may be operable to detect such particles that are byproducts of the EBID or EBIE process.

Similar to the previous description with reference to FIG. 2, the system 20A may include a single third gas analysis device 222, as depicted, or may include two or more third gas analysis devices 222, in some embodiments. For example, two or more different third gas analysis devices 222 may be mounted to the sidewall of the chamber 220. The two or more different third gas analysis devices 222 may be operable to detect different gas(es) and/or particulate byproducts from each other, so that two or more types of gas analysis may be performed (e.g., leakage and outgassing). Based on the two or more types of gas analysis, various actions may be performed, such as identifying and repairing a leak, cleansing or removing contaminants causing outgassing, adjusting process parameters to reduce production of particulate byproducts, and the like.

As depicted in FIG. 3, in some embodiments, the system 20A includes a fourth gas analysis device 262. The fourth gas analysis device 262 is coupled to an exhaust line 268 that connects the pumping system 260 to the chamber 220. For example, the exhaust line 268 may be an exhaust line that is connected between the turbo pump 266 and the chamber 220. The fourth gas analysis device 262 may be in fluid communication with the exhaust line 268, such that exhaust gas removed from the chamber 220 may flow into the fourth gas analysis device 262. The fourth gas analysis device 262 may be similar in most respects to the first, second and/or third gas analysis devices 252, 212, 222 described previously with reference to FIGS. 2 and 3. Namely, the fourth gas analysis device 262 may be or include a residual gas analyzer, mass spectrometer, PID, or the like. In some embodiments, the fourth gas analysis device 262 includes two or more gas analysis devices that may be the same type with different configurations from each other or different types from each other. For example, two or more different fourth gas analysis devices 262 may be mounted to the exhaust line 264. The two or more different fourth gas analysis devices 262 may be operable to detect different gas(es) and/or particulate byproducts from each other, so that two or more types of gas analysis may be performed (e.g., leakage and outgassing). Based on the two or more types of gas analysis, various actions may be performed, such as identifying and repairing a leak, cleansing or removing contaminants causing outgassing, adjusting process parameters to reduce production of particulate byproducts, and the like.

FIG. 4 is a diagrammatic schematic view of a system 20B in accordance with various embodiments. The system 20B may be an embodiment of the system 12 of FIG. 1B and may be similar in most respects to the systems 20 and 20A of FIGS. 2 and 3. Some components are omitted from view in FIG. 4 for simplicity of illustration.

The system 20B may include a fifth gas analysis device 232 and a sixth gas analysis device 272. The fifth gas analysis device 232 and the sixth gas analysis device 272 may be any of the gas analysis devices described with reference to FIG. 2. Namely, the fifth and sixth gas analysis devices 232, 272 may each perform one or more of mass spectrometry, Fourier transform infrared spectroscopy (FTIR), electrochemical sensing, photoionization detection, residual gas analysis, ion mobility spectrometry (IMS), or the like.

The fifth gas analysis device 232 may be connected to the loading chamber 230. For example, the fifth gas analysis device 232 may be mounted to a sidewall of the loading chamber 230 and may be in fluid communication with the loading chamber 230, such that a gas medium inside the loading chamber 230 may flow into the fifth gas analysis device 232 from the loading chamber 230. The fifth gas analysis device 232 may be operable to detect environmental gas(es) (e.g., H2O, CO, CO2, H2, N2, O2, CxHyOz), outgassing of contaminants and/or process byproducts. For example, the fifth gas analysis device 232 may be operable to detect leakage of external environmental air into the loading chamber 230 and/or incomplete evacuation of external environmental air via the pumping system 270. The fifth gas analysis device 232 may be operable to detect outgassing of contaminants. For example, the contaminants may be present on inner walls of the loading chamber 220, the robot arm 234, or both. The fifth gas analysis device 232 may be operable to detect byproducts of the EBID or EBIE process that float into the loading chamber 220. For example, some material particles formed by the reacted gas(es) may not deposit or attach on the surface of the mask 218, but instead may float in the processing chamber 220, then may move to the loading chamber 230 during retrieval of the mask 218 from the processing chamber 220. The fifth gas analysis device 232 may be operable to detect such particles that are byproducts of the EBID or EBIE process.

Similar to the previous description with reference to FIG. 2, the system 20B may include a single fifth gas analysis device 232, as depicted, or may include two or more fifth gas analysis devices 232, in some embodiments. For example, two or more different fifth gas analysis devices 232 may be mounted to the sidewall of the loading chamber 230. The two or more different fifth gas analysis devices 232 may be operable to detect different gas(es) and/or particulate byproducts from each other, so that two or more types of gas analysis may be performed (e.g., leakage and outgassing). Based on the two or more types of gas analysis, various actions may be performed, such as identifying and repairing a leak, cleansing or removing contaminants causing outgassing, adjusting process parameters to reduce production of particulate byproducts, and the like.

As depicted in FIG. 4, in some embodiments, the system 20B includes a sixth gas analysis device 272. The sixth gas analysis device 272 is coupled to an exhaust line 278 that connects the pumping system 270 to the loading chamber 230. For example, the exhaust line 278 may be an exhaust line that is connected between the turbo pump 276 and the loading chamber 230. The sixth gas analysis device 272 may be in fluid communication with the exhaust line 278, such that environmental atmospheric gas exhausted from the loading chamber 230 by the pumping system 270 may flow into the sixth gas analysis device 272. The sixth gas analysis device 272 may be similar in most respects to the first, second, third, fourth and/or fifth gas analysis devices 252, 212, 222, 262, 232 described previously with reference to FIGS. 2-4. Namely, the sixth gas analysis device 272 may be or include a residual gas analyzer, mass spectrometer, PID, or the like. In some embodiments, the sixth gas analysis device 272 includes two or more gas analysis devices that may be the same type with different configurations from each other or different types from each other. For example, two or more different sixth gas analysis devices 272 may be mounted to the exhaust line 274. The two or more different sixth gas analysis devices 272 may be operable to detect different gas(es) and/or particulate byproducts from each other, so that two or more types of gas analysis may be performed (e.g., leakage and outgassing). Based on the two or more types of gas analysis, various actions may be performed, such as identifying and repairing a leak, cleansing or removing contaminants causing outgassing, adjusting process parameters to reduce production of particulate byproducts, and the like.

In the above description referencing FIGS. 2-4, the gas analysis devices 252, 212, 222, 262, 232, 272 are operable to determine chemical composition of gas mediums in the column 210, the processing chamber 220 and/or the loading chamber 230. In some embodiments, the systems 20, 20A, 20B may include gas flow analysis device(s) that is/are operable to determine other non-chemical characteristics of the gas mediums. For example, one or more mass flow controllers (MFCs) may be coupled to the transport line(s) 284 that deliver process gas(es) into the processing chamber 220. A gas flow analysis device may be coupled to the MFC to detect level of flow of the one or more process gases (or purge gases) into the chamber 220. Generally, reference to “gas analysis devices” throughout the description refers to chemical composition analysis devices instead of flow analysis devices.

As mentioned previously, the embodiments depicted in FIGS. 2-4 may be combined. For example, the system 20 may include any combination of one or more (e.g., all) of the first, second, third, fourth, fifth and sixth gas analysis devices 252, 212, 222, 262, 232, 272.

Inclusion of the gas analysis devices 252, 212, 222, 262, 232, 272 is beneficial to provide detection of outgassing, leakage, impurities, byproducts in the column 210, processing chamber 220 and loading chamber 230 during repair of the mask 218. The various forms of detection can be beneficial to prevent aperture and/or lens contamination, improve process stability and improve mask repair yield.

FIG. 5 is a flowchart diagram of a method 1000 of performing in-situ abnormality detection by one or more gas analysis devices during a mask repair process in an e-beam or ion beam repair apparatus in accordance with various embodiments. The method 1000 may be performed by the systems 20, 20A, 20B described with reference to FIGS. 2-4, or by a similar system that has fewer or additional components relative to those of the systems 20, 20A, 20B. In some embodiments, one or more operations of the method 1000 are performed or controlled by a controller, such as the controller 135 described with reference to FIG. 1B. For example, the controller 135 may be in electrical and/or data communication with the gas analysis device(s) 252, 212, 222, 262, 232, 272 to control operation of and/or receive data from the gas analysis device(s) 252, 212, 222, 262, 232, 272.

In FIG. 5, the method 1000 begins with act 1010, which is positioning a mask in a loading chamber of an electron beam or ion beam mask repair apparatus. For example, the mask 218 may be positioned in the loading chamber 230 of the e-beam or ion beam mask repair apparatus 20, 20A, 20B. In act 1010, the mask 218 may be positioned in the loading chamber 230 by the robot arm 234, which may remove the mask 218 from a carrier and retract to position the mask 218 in the loading chamber 230. Then, a door of the loading chamber 234 may be closed to prepare for pulling vacuum in the loading chamber 234 via the pumping system 270.

Following act 1010, the method 1000 proceeds to act 1020. Act 1020 follows act 1010. In act 1020, a vacuum is formed in the loading chamber with the mask positioned therein. For example, the vacuum may be formed in the loading chamber 230 via the pumping system 270 with the mask 218 therein. Formation of the vacuum may include one or more operations. For example, the dry pump 274 may form an initial, lower vacuum (e.g., higher pressure) in the loading chamber 230, then the turbo pump 276 may form a second, higher vacuum (e.g., UHV, lower pressure) in the loading chamber 230.

Act 1070 follows or is performed simultaneously with act 1020. Act 1070 may also be performed following or simultaneously with acts 1030, 1050 and 1060, as depicted, and will be also described in detail with reference to each of acts 1030, 1050 and 1060. Act 1070 includes detecting one or more abnormalities in operation of the mask repair apparatus or system (e.g., systems 20, 20A, 20B) via one or more gas analysis devices (e.g., the gas analysis devices 252, 212, 222, 262, 232, 272). In the context of act 1020, during and/or following formation of the vacuum in the loading chamber, in act 1070, one or more abnormalities may be detected, such as outgassing of contaminants and/or leakage from an external environment. For example, the fifth gas analysis device 232 and/or the sixth gas analysis device 272 may detect chemical composition of a gas medium in and/or exhausted from the loading chamber 230. The chemical composition of the gas medium may include one or more gases associated with the external environment due to leakage of the loading chamber 230, one or more gases associated with outgassing by contaminants (e.g., particulates) in the loading chamber 230, combinations thereof and the like.

Act 1080 follows act 1070. In act 1080, a determination is made whether an abnormality is detected in the gas medium in and/or exhausted from the loading chamber (e.g., the loading chamber 230). Act 1080 may be performed by a controller that is in data communication with the gas analysis devices that analyze the gas medium of the loading chamber. In some embodiments, the determination includes one or more of determining level(s) of one or more constituents of the gas medium and determining whether the level(s) exceed a threshold value. Based on the determination, the method 1000 may proceed from the act 1080 to act 1090 or to one or more of acts 1030, 1040, 1050 or 1060. Namely, in some embodiments, act 1030 or act 1040, which may follow act 1020, may be performed only if no abnormality is detected via the gas analysis device(s) that analyze gas output of the loading chamber. In some embodiments, acts 1030 and/or 1040 may be performed regardless of whether an abnormality or abnormalities is detected via the gas analysis device(s) associated with act 1020. For example, when a leakage abnormality is detected in the loading chamber 230, the method 1000 may proceed to act 1090 to repair the leakage, as the leakage may impair ability to draw vacuum in the loading chamber 230, which can introduce environmental gas contaminants into the processing chamber 220 when the mask 218 is transferred from the loading chamber 230 to the processing chamber 220. In another example, when an outgassing abnormality is detected in the loading chamber 230, cleaning of the loading chamber 230 in act 1090 to remove the contaminant source of the outgassing may be delayed until after the mask 218 currently being repaired has completed the repair process (e.g., after act 1060). However, above a selected threshold level, the outgassing may be at a level associated with a sufficiently high likelihood that repair of the mask 218 will fail. In such an example, the mask 218 may be removed from the loading chamber 230 so that the loading chamber 230 may be cleaned in act 1090 prior to reloading the mask 218 into the loading chamber 230 in act 1010 in preparation for repair in the processing chamber 220 in act 1060.

Act 1030 follows act 1020. In act 1030, a vacuum is formed in the processing chamber (e.g., the processing chamber 220) and a vacuum is formed in a column (e.g., the column 210). The vacuum in the column 210 may be formed via an IGP, such as the IGP 250. The vacuum in the processing chamber 220 may be formed via a pumping system, such as the pumping system 260, and may include one or more operations, similar to that described with reference to act 1020. Namely, the dry pump 264 may form the vacuum at a first level that is relatively low (e.g., higher pressure), then the turbo pump 266 may form the vacuum at a second level that is relatively high (e.g., UHV, lower pressure). In some embodiments, the vacuum level in the processing chamber 220 is about the same as the vacuum level in the loading chamber 230 to avoid flow of gas from the loading chamber 230 to the processing chamber 220 during transfer of the mask 218 to the processing chamber 220. In some embodiments, the vacuum levels are different from each other. The forming a vacuum in the column and the forming a vacuum in the processing chamber may be performed simultaneously in a single act, as depicted in FIG. 5, or may be performed at different times in two different acts. Namely, the forming a vacuum in the column may precede the forming a vacuum in the processing chamber, or the forming a vacuum in the processing chamber may precede the forming a vacuum in the column, in some embodiments.

Act 1070 follows or is performed simultaneously with act 1030. In the context of act 1030, during and/or following formation of the vacuum in the processing chamber and/or in the column, in act 1070, one or more abnormalities may be detected, such as outgassing of contaminants and/or leakage from an external environment. For example, the third gas analysis device 222 and/or the fourth gas analysis device 262 may detect chemical composition of a gas medium in and/or exhausted from the processing chamber 220. In another example, the first gas analysis device 252 and/or the second gas analysis device 212 may detect chemical composition of a gas medium in and/or exhausted from the column 210. The chemical composition of either gas medium may include one or more gases associated with the external environment due to leakage of the processing chamber 220 or column 210, one or more gases associated with outgassing by contaminants (e.g., particulates) in the processing chamber 220 or column 210, combinations thereof and the like.

Act 1080 follows act 1070. In act 1080, a determination is made whether an abnormality is detected in the gas medium in and/or exhausted from the processing chamber (e.g., the processing chamber 220) or column. In some embodiments, the determination includes one or more of determining level(s) of one or more constituents of one or both of the gas mediums and determining whether the level(s) exceed a threshold value. Based on the determination, the method 1000 may proceed from the act 1080 to act 1090 or to one or more of acts 1040, 1050 or 1060. Namely, in some embodiments, act 1040, which may follow act 1030, may be performed only if no abnormality is detected via the gas analysis device(s) that analyzes gas output of the processing chamber or column. In some embodiments, act 1040 may be performed regardless of whether an abnormality or abnormalities is detected via the gas analysis device(s) associated with act 1030. For example, when a leakage abnormality is detected in the processing chamber 220 or the column 210, the method 1000 may proceed to act 1090 to repair the leakage, as the leakage may impair ability to draw vacuum in the processing chamber 220 or the column 210, which can introduce environmental gas contaminants into the processing chamber 220 or the column 210 when the mask 218 is repaired in act 1060. In another example, when an outgassing abnormality is detected in the processing chamber 220 or the column 210, cleaning of the processing chamber 220 or column 210 in act 1090 to remove the contaminant source of the outgassing may be delayed until after the mask 218 currently being repaired has completed the repair process (e.g., after act 1060). However, above a selected threshold level, the outgassing may be at a level associated with a sufficiently high likelihood that repair of the mask 218 will fail. In such an example, the mask 218 may be held in or removed from the loading chamber 230 so that the processing chamber 220 and/or column 210 may be cleaned in act 1090 prior to loading the mask 218 into the processing chamber 220 in act 1040 in preparation for repair in the processing chamber 220 in act 1060.

Act 1040 follows act 1030. Following forming the vacuum in the loading chamber, the processing chamber and the column, the mask may be transferred from the loading chamber to the processing chamber in act 1040. For example, the mask 218 may be transferred from the loading chamber 230 to the mask stage 224 of the processing chamber 220.

Act 1050 follows act 1040. Following transferring the mask to the processing chamber, process gas(es) may be flowed into the processing chamber in act 1050. The process gas(es) may be or include reaction gases for EBID or EBIE, purge gases (e.g., N2, Ar, etc.), or both. For example, the process gas(es) may be flowed into the processing chamber 220 from the gas supply 280 via the transport line 284. During or following flowing of the process gas(es) into the processing chamber 220 in act 1050, abnormalities may be detected in act 1070.

In the context of act 1050, during and/or following flowing of process gas(es) into the processing chamber, in act 1070, one or more abnormalities may be detected, such as impurities in the process gas(es), outgassing of contaminants and/or leakage from an external environment. For example, the third gas analysis device 222 and/or the fourth gas analysis device 262 may detect chemical composition of a gas medium in and/or exhausted from the processing chamber 220. The chemical composition of the gas medium may include one or more impurities associated with the process gas(es) due to, for example, contamination of the gas supply 280. Although leaks and/or outgassing of contaminants may be detected during and/or following forming the vacuum in the processing chamber 220, the leaks and/or outgassing may continue to be detected during and/or following the flowing of process gas(es) into the processing chamber from the gas supply 280.

Act 1080 follows act 1070. In act 1080, a determination is made whether an abnormality is detected in the gas medium in and/or exhausted from the processing chamber (e.g., the processing chamber 220). In some embodiments, the determination includes one or more of determining level(s) of one or more constituents (e.g., impurities) of the gas medium and determining whether the level(s) exceed a threshold value. Based on the determination, the method 1000 may proceed from the act 1080 to act 1090 or to act 1060. Namely, in some embodiments, act 1060, which may follow act 1050, may be performed only if no abnormality (e.g., impurity in process gases) is detected via the gas analysis device(s) that analyzes gas output of the processing chamber. In some embodiments, act 1060 may be performed regardless of whether an abnormality or abnormalities is detected via the gas analysis device(s) associated with act 1050. For example, when a process gas impurity abnormality is detected in the processing chamber 220, the method 1000 may proceed to act 1090 to repair the gas supply 280 and/or the transport line 284, as the impurity may impair ability to deposit and/or etch the mask 218 when the mask 218 is repaired in act 1060. In another example, when an outgassing abnormality is detected in the processing chamber 220, cleaning of the processing chamber 220 in act 1090 to remove the contaminant source of the outgassing may be delayed until after the mask 218 currently being repaired has completed the repair process (e.g., after act 1060). However, above a selected threshold level, the outgassing may be at a level associated with a sufficiently high likelihood that repair of the mask 218 will fail. In such an example, the mask 218 may be removed from the processing chamber 220 so that the processing chamber 220 may be cleaned in act 1090 prior to reloading the mask 218 into the processing chamber 220 (e.g., returning to act 1040) in preparation for repair in the processing chamber 220 in act 1060.

Act 1060 follows or is performed simultaneously with act 1050. Following or during flowing the process gas(es) into the processing chamber, the mask may be repaired by the e-beam (e.g., EBID, EBIE) or the ion beam in act 1060. The repair in act 1060 may include one or both of subtractive repair (e.g., EBIE) and additive repair (e.g., EBID). In the subtractive repair, the mask may include excess material thereon. As such, the e-beam or ion beam can be used to locally mill or etch away the excess material. The e-beam or ion beam is controlled to remove the defect, leaving the surrounding area intact. In additive repair, material may be missing or a clear defect is present, and the e-beam or ion beam may be used to deposit material onto the mask. This may be achieved through electron-beam-induced deposition (EBID), where a gas precursor is introduced into the processing chamber and decomposed by the e-beam or ion beam to leave behind the selected material. Gas precursors that may be flowed in act 1050 for additive e-beam mask repair may include one or more gas precursors for depositing carbon-based materials (e.g., methane, ethylene, or the like), metallic materials (e.g., tungsten hexafluoride for tungsten deposition, trimethylaluminum for aluminum deposition, or the like), insulating materials (e.g., tetraethylorthosilicate for silicon dioxide, silicon tetrachloride for silicon-based insulators, or the like), other materials (e.g., copper acetylacetonate for copper, titanium tetrachloride for titanium, or the like), or mixed compositions (e.g., organometallic compounds for compound semiconductors or other alloy materials) and the like. During or following repairing of the mask in act 1060, abnormalities may be detected in act 1070.

In the context of act 1060, during and/or following repairing the mask, in act 1070, one or more abnormalities may be detected, such as reaction byproducts in the exhaust gas. For example, the third gas analysis device 222 and/or the fourth gas analysis device 262 may detect chemical composition of a gas medium in and/or exhausted from the processing chamber 220. The chemical composition of the gas medium may include one or more byproducts associated with the EBID or EBIE process, for example, due to improper or insufficiently precise configuration of parameters of the EBID or EBIE process. For example, flow rate of one or more of the process gases may be such that a high level of byproducts is formed outside of the deposition or etching that is being performed on the surface of the mask. In another example, although leaks and/or outgassing of contaminants may be detected during and/or following forming the vacuum or flowing the process gas(es) in the processing chamber 220, the leaks and/or outgassing may continue to be detected during and/or following the repairing of the mask in the processing chamber via the e-beam or ion beam.

Act 1080 follows act 1070. In act 1080, a determination is made whether an abnormality is detected in the gas medium in and/or exhausted from the processing chamber (e.g., the processing chamber 220). In some embodiments, the determination includes one or more of determining level(s) of one or more constituents (e.g., byproducts) present in the gas medium and determining whether the level(s) exceed a threshold value. Based on the determination, the method 1000 may proceed from the act 1080 to act 1090 or to act 1060. Namely, in some embodiments, act 1060, which may be performed simultaneously with the detection and determination of acts 1070 and 1080, may be continued only if no abnormality (e.g., high level of byproducts in exhaust gas) is detected via the gas analysis device(s) that analyzes gas output of the processing chamber. In some embodiments, act 1060 may continue to be performed regardless of whether an abnormality or abnormalities is detected via the gas analysis device(s) associated with act 1060. For example, when a process gas byproducts abnormality is detected in the processing chamber 220, the method 1000 may delay proceeding to act 1090 to adjust reaction parameters, as the repair of the mask may already be partially completed in act 1060 and halting the repair may result in scrapping the mask. In another example, when the repair process may be halted without scrapping the mask, when the byproduct level in the exhaust gas is above a selected threshold level, the byproduct level may be at a level associated with a sufficiently high likelihood that repair of the mask 218 will fail. In such an example, repair of the mask 218 may be halted and the mask 218 may be removed from the processing chamber 220 (e.g., to the loading chamber 230) so that processing parameters may be adjusted in act 1090 prior to reloading the mask 218 into the processing chamber 220 (e.g., returning to act 1040) in preparation for repair in the processing chamber 220 in act 1060 using the new parameters.

Additional acts may follow act 1060. For example, following repair of the mask, the mask may be removed from the processing chamber to the loading chamber, then may be removed from the loading chamber to a carrier external to the mask repair apparatus. In some embodiments, the mask may then be installed in a lithography apparatus (e.g., an EUV stepper) for production of semiconductor wafers. A method 2000 in accordance with various embodiments for producing semiconductor wafers using a mask repaired according to method 1000 is described in greater detail with reference to FIG. 6.

FIG. 6 is a flowchart of method 2000 in accordance with various embodiments.

In FIG. 6, the method 2000 begins with act 2010, which includes forming a repaired mask in a mask repair apparatus (e.g., the system 20, 20A, 20B) that includes an e-beam or ion beam generator and one or more gas analysis devices, as described with reference to FIGS. 1B-4. Act 2010 may include substantially the same or most of the acts of method 1000 described with reference to FIG. 5.

Act 2020 follows act 2010. Following forming the repaired mask in act 2010, the repaired mask is installed in a processing apparatus, such as the lithography system 10 depicted in FIG. 1A. For example, the repaired mask may be mounted to the mask stage 16 of the lithography system 10.

Act 2030 may follow or precede act 2020. In act 2030, the wafer may be the wafer 22 and may include one or more semiconductor devices, which may be complete or in an intermediate stage of processing. The wafer 22 may have a masking layer 26 thereon, such as a photoresist layer that may be patterned via exposure to EUV light generated by the lithography system 10. The semiconductor device may be any semiconductor device, such as, but not limited to, a logic device, a memory device or any other semiconductor device. The semiconductor device generally includes a semiconductor device layer, a frontside interconnection structure, an optional backside interconnection structure and one or more electrical contacts. In most embodiments, the wafer is a semiconductor wafer that has multiple integrated circuit (IC) chips or dies formed therein. The semiconductor device layer may include a semiconductor substrate, which may be referred to as the substrate. The substrate may be any suitable substrate. In some embodiments, the substrate may be a semiconductor wafer. In some embodiments, the substrate may be a monocrystalline silicon (Si) wafer, an amorphous Si wafer, a gallium arsenide (GaAs) wafer, or any other semiconductor wafer.

The semiconductor device layer includes one or more semiconductor devices. The semiconductor devices included within the semiconductor device layer may be any semiconductor devices in various embodiments. In some embodiments, the semiconductor device layer includes one or more transistors, which may include any suitable transistor structures, including, for example, planar transistors, fin-type transistors (FinFETs), or nanostructure transistors, such as gate-all-around (GAA) transistors, or the like. In some embodiments, the semiconductor device layer includes one or more GAA transistors. In some embodiments, the semiconductor device layer may be a logic layer that includes one or more semiconductor devices, and may further include their interconnection structures, that are configured and arranged to provide a logical function, such as AND, OR, XOR, XNOR, or NOT, or a storage function, such as a flipflop or a latch. In some embodiments, the semiconductor device layer may include a memory device, which may be any suitable memory device, such as, for example, a static random access memory (SRAM) device. The memory device may include a plurality of memory cells that are constructed in rows and columns, although other embodiments are not limited to this arrangement. Each memory cell may include multiple transistors (e.g., six) connected between a first voltage source (e.g., VDD) and a second voltage source (e.g., VSS or ground) such that one of two storage nodes can be occupied by the information to be stored, with the complementary information stored at the other storage node. The semiconductor device layer of the device may further include various circuitry that is electrically coupled to the semiconductor device layer. For example, the semiconductor device layer may include power management or other circuitry that is electrically coupled to the one or more semiconductor devices of the semiconductor device layer. The power management circuitry may include any suitable circuitry for controlling or otherwise managing communication signals, such as input power signals, to or from the semiconductor devices of the semiconductor device layer. In some embodiments, the power management circuitry may include power-gating circuitry which may reduce power consumption, for example, by shutting off the current to blocks of the circuit (e.g., blocks or electrical features in the semiconductor device layer) that are not in use, thereby reducing stand-by or leakage power. In some embodiments, the semiconductor device layer includes one or more switching devices, such as a plurality of transistors, that are used to transmit or receive electrical signals to and from the semiconductor devices in the semiconductor device layer, such as to turn on and turn off the circuitry (e.g., transistors, etc.) of the semiconductor device layer.

Act 2040 follows acts 2020 and 2030. With the repaired mask and the semiconductor wafer in place in a chamber of the processing apparatus (e.g., the lithography system 10), light is directed at the repaired mask in act 2040. The light may be EUV light, such as the light 84 generated by the light source 120 described with reference to FIG. 1A. The light may impinge on the repaired mask directly or may pass through a pellicle that is mounted on and protects the repaired mask. The light may be light that exits an illuminator (e.g., the illuminator 140) to be incident on the repaired mask. The repaired mask may be translated in a horizontal plane by the masks stage 16, such that the light, which may be a stripe, may scan across the repaired mask.

Act 2050 follows act 2040. Following directing the light at the repaired mask in act 2040, the light is reflected by the repaired mask based on a pattern thereof, and a layer of the semiconductor wafer is patterned by or based on reflected light having the pattern of the repaired mask in act 2050. For example, the reflected light having the pattern of the repaired mask may be incident on the photoresist layer 26 via the POB 180. The pattern may thus be transferred to the photoresist layer 26. Then, the photoresist layer 26 may be processed to remove or keep portions of the photoresist layer 26 that were exposed to the reflected light. Following patterning of the photoresist layer 26, which forms openings in the photoresist layer 26, one or more material layers underlying the photoresist layer 26 and exposed by the openings may be etched to transfer the pattern of the photoresist layer 26 to the underlying material layer(s).

Embodiments may provide advantages. Repairing the mask by the mask repair apparatus 20, 20A, 20B including the gas analysis device(s) 212, 252, 222, 232, 262, 272 may allow for early and accurate detection of contaminants, leaks, impurities and byproducts, which can improve yield of the mask repair apparatus 20, 20A, 20B and lengthen lifespan of components of the mask repair apparatus 20, 20A, 20B, such as the aperture and/or lens of the column 210.

In accordance with at least one embodiment, a method includes: positioning a mask in a processing chamber of a mask repair apparatus; determining whether a first abnormality is present by a first gas analysis device during forming a first vacuum in a column over the processing chamber; determining whether a second abnormality is present by a second gas analysis device during forming a second vacuum in the processing chamber; determining whether a third abnormality is present by a third gas analysis device during flowing a process gas into the processing chamber; determining whether a fourth abnormality is present by a fourth gas analysis device during directing an electron beam or ion beam at the mask with the process gas in the processing chamber; and in response to determining that one of the first, second, third or fourth abnormalities is present: halting the directing an electron beam or ion beam at the mask; and performing a repair associated with the first, second, third or fourth abnormality that is present.

In accordance with at least one embodiment, a method includes: forming a repaired mask by a mask repair apparatus including an electron beam source or ion beam source therein, the forming including: detecting at least one abnormality via a gas analysis device mounted to at least one of a column, a processing chamber or a loading chamber of the mask repair apparatus; positioning the repaired mask in a lithography apparatus; positioning a semiconductor wafer in the lithography apparatus; and patterning a mask layer of the semiconductor wafer based on a pattern of the repaired mask.

In accordance with at least one embodiment, a system includes: a processing chamber having a mask stage therein; a column over the processing chamber, the column having a beam source therein; a loading chamber adjacent the processing chamber; a first pumping system connected to the processing chamber; a second pumping system connected to the loading chamber; an ion getter pump connected to the column; and at least one of: a first gas analysis device mounted to a first transport line of the ion getter pump; a second gas analysis device mounted to a first wall of the column; a third gas analysis device mounted to a second wall of the processing chamber; a fourth gas analysis device mounted to a first exhaust line of the first pumping system; a fifth gas analysis device mounted to a third wall of the loading chamber; or a sixth gas analysis device mounted to a second exhaust line of the second pumping system.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
positioning a mask in a processing chamber of a mask repair apparatus;
determining whether a first abnormality is present by a first gas analysis device during forming a first vacuum in a column over the processing chamber;
determining whether a second abnormality is present by a second gas analysis device during forming a second vacuum in the processing chamber;
determining whether a third abnormality is present by a third gas analysis device during flowing a process gas into the processing chamber;
determining whether a fourth abnormality is present by a fourth gas analysis device during directing an electron beam or ion beam at the mask with the process gas in the processing chamber; and
in response to determining that one of the first, second, third or fourth abnormalities is present:
halting the directing an electron beam or ion beam at the mask; and
performing a repair associated with the first, second, third or fourth abnormality that is present.

2. The method of claim 1, wherein the determining whether a first abnormality is present includes:
determining whether outgassing by a contaminant in the column is present; or
determining whether a leak in the column is present.

3. The method of claim 2, wherein the determining whether outgassing is present includes analyzing a gas medium of the column via the first gas analysis device mounted to a transport line in communication with an ion getter pump.

4. The method of claim 2, wherein the determining whether a leak is present includes analyzing a gas medium of the column via a residual gas analysis device mounted to a wall of the column.

5. The method of claim 1, wherein the determining whether a second abnormality is present includes:
exhausting a gas medium of the processing chamber by a pumping system; and
analyzing the gas medium by the second gas analysis device.

6. The method of claim 5, wherein the exhausting a gas medium includes:
forming the second vacuum by a first pump that includes a dry pump or a scroll pump and by a second pump that includes a turbo pump;
wherein the analyzing the gas medium includes analyzing the gas medium by the second gas analysis device mounted to an exhaust line that is between the processing chamber and the turbo pump.

7. The method of claim 1, wherein the determining whether a third abnormality is present includes:
determining whether an impurity is present in the process gas at a level greater than a threshold value.

8. The method of claim 1, wherein the determining whether a fourth abnormality is present includes:
determining whether a reaction byproduct is present in a gas medium exhausted from the processing chamber at a level greater than a threshold value.

9. A method comprising:
forming a repaired mask by a mask repair apparatus including an electron beam source or ion beam source therein, the forming including:
detecting at least one abnormality via a gas analysis device mounted to at least one of a column, a processing chamber or a loading chamber of the mask repair apparatus;
positioning the repaired mask in a lithography apparatus;
positioning a semiconductor wafer in the lithography apparatus; and
patterning a mask layer of the semiconductor wafer based on a pattern of the repaired mask.

10. The method of claim 9, wherein the detecting includes at least one of:
detecting a leak in the loading chamber; or
detecting outgassing of a contaminant in the loading chamber.

11. The method of claim 9, wherein the detecting includes at least one of:
detecting a leak in the column; or
detecting outgassing of a contaminant in the column.

12. The method of claim 9, wherein the detecting includes at least one of:
detecting a leak in the processing chamber;
detecting an impurity in process gas flowed into the processing chamber; or
detecting outgassing of a contaminant in the processing chamber.

13. The method of claim 9, wherein the forming a repaired mask includes:
performing electron-beam-induced deposition (EBID) on a mask; and
detecting a level of a particulate byproduct resulting from the EBID by the gas analysis device.

14. The method of claim 9, wherein the forming a repaired mask includes:
performing electron-beam-induced etching (EBIE) on a mask; and
detecting a level of a particulate byproduct resulting from the EBIE by the gas analysis device.

15. A system, comprising:
a processing chamber having a mask stage therein;
a column over the processing chamber, the column having a beam source therein;
a loading chamber adjacent the processing chamber;
a first pumping system connected to the processing chamber;
a second pumping system connected to the loading chamber;
an ion getter pump connected to the column; and
at least one of:
a first gas analysis device mounted to a first transport line of the ion getter pump;
a second gas analysis device mounted to a first wall of the column;
a third gas analysis device mounted to a second wall of the processing chamber;
a fourth gas analysis device mounted to a first exhaust line of the first pumping system;
a fifth gas analysis device mounted to a third wall of the loading chamber; or
a sixth gas analysis device mounted to a second exhaust line of the second pumping system.

16. The system of claim 15, wherein at least one of the first, second, third, fourth, fifth or sixth gas analysis devices includes a residual gas analyzer.

17. The system of claim 16, wherein at least one of the first or second gas analysis device is operable to detect a level of a gas associated with outgassing of a contaminant in the column.

18. The system of claim 16, wherein at least one of the first, second, third, fourth, fifth or sixth gas analysis devices is operable to detect a level of external environmental gas associated with a leak in the column, a leak in the processing chamber or a leak in the loading chamber.

19. The system of claim 16, wherein at least one of the third or fourth gas analysis devices is operable to detect a level of impurity in a process gas supplied to the processing chamber.

20. The system of claim 16, wherein at least one of the third or fourth gas analysis devices is operable to detect a level of a reaction byproduct resulting from an electron-beam-induced deposition (EBID) or electron-beam-induced etch (EBIE) performed on a semiconductor wafer positioned in the processing chamber.
